(19) United States
(12) Patent Application Publication
(10) Pub. No.: US 2021/0278721 A1
(43) Pub. Date: Sep. 9, 2021

(54) DISPLAY PANEL AND DISPLAY DEVICE

(71) Applicant: TCL China Star Optoelectronics Technology Co., Ltd., Shenzhen (CN)

(72) Inventor: Yun YU, Shenzhen (CN)

(73) Assignee: TCL China Star Optoelectronics Technology Co., Ltd., Shenzhen (CN)

(21) Appl. No.: 16/624,321

(22) PCT Filed: Nov. 12, 2019
(86) PCT No.: PCT/CN2019/117644

§ 371 Date: Dec. 19, 2019

(30) Foreign Application Priority Data
Aug. 21, 2019 (CN) 201910771407.7

(51) Int. Cl. G02F 1/1335; H01L 23/544

(52) U.S. Cl. CPC G02F 1/133512; H01L 2223/54426; G02F 1/133514; H01L 23/544

(57) ABSTRACT

The invention discloses a display panel and a display device. The display panel includes a display area and a non-display area. A marked area is arranged in the non-display area and includes at least two marks. A light shielding area is provided with a light shielding layer, the light shielding layer is laminated on the marked area of the non-display area, and openings corresponding to the at least two marks are defined in the light shielding layer.

### FIELD OF INVENTION

The present disclosure relates to the field of displays, and particularly relates to a display panel and a display device.

### BACKGROUND OF INVENTION

With the development of display technology, flat display devices, such as liquid crystal displays (LCDs) consisting of liquid crystal display panels have become mainstream display devices widely used in various consumer electronic products, such as mobile phones, televisions, personal digital assistants, digital cameras, notebook computers, desktop computers, etc., due to advantages including high image quality, power saving, thin body, and no radiation. However, outer frames of traditional liquid crystal displays have a certain width covering a surrounding surface of the liquid crystal display panels, so that there is a visual impression that a display area of the displays is reduced. In order to increase the display area under same display dimensions, a borderless design of the liquid crystal display panels has become an important trend in the development of today's display technology.

In a manufacturing process of borderless liquid crystal display panels, the cell process is important, in which a prepared color film substrate and an array substrate are treated by a series of processes to form a qualified liquid crystal display screen. The cell process generally includes: after dropping an appropriate amount of liquid crystals on the array substrate, laminating the color film substrate and the array substrate under vacuum, and dividing a large substrate having the laminated color film substrate and the laminated array substrate into single screens according to dimensions of the finished liquid crystal displays. Alignment marks are used in both of the above processes.

As shown in FIG. 1, in order to improve aesthetics of the display and improve customer experience, more and more displays use bezel-less (without front frame/less front frame) technology. Bezel-less displays have higher quality requirements for non-display areas on peripheral edges than normal panels. There are many hollow marks in the non-display area of the panel; if the front panel is reduced or not used, a hollow area will be exposed and light leakage will occur, which will seriously affect the quality of the display.

### Technical Problem

In prior arts, an opening must be formed on a light shielding layer of the color film substrate to ensure that the marks are exposed on the color film substrate, and a problem of light leakage of the display panel is caused as dimensions of the opening are larger than those of the marks. In order to solve the above problem, the present disclosure provides a display panel and a display device.

### SUMMARY OF INVENTION

To solve the above problems, the technical solutions provided by the present disclosure are as follows:

The present disclosure provides a display panel including a display area and a non-display area surrounding the display area; a marked area is arranged in the non-display area and includes at least two marks; a light shielding area is provided with a light shielding layer, the light shielding layer is laminated on the marked area of the non-display area, and openings corresponding to the marks are defined in the light shielding layer.

Furthermore, the display panel further includes an array substrate located in the non-display area, the marks are arranged on the array substrate; and a color film substrate opposite to the array substrate and located in the non-display area, wherein the light shielding layer is laminated on the color film substrate.

Furthermore, shapes of the openings are the same as these of the marks; and dimensions of the openings are the same as these of the masks.

Furthermore, a projection on the marked area of the opening completely falls within an area of the mark.

Furthermore, dimensions of the opening are about 3 μm to 5 μm less than that of the mark.

Furthermore, the mark is made of opaque metal materials.

Furthermore, a maximum diameter of the mark is less than 0.3 mm.

Furthermore, the marks are distributed around the array substrate.

Furthermore, shapes of the marks are at least one of a cross shape, a square shape, an L shape, and a circular shape.

The present disclosure also provides a display device including the display panel.

### Beneficial Effect

The display panel and the display device of the present disclosure provide an effective solution to the problem that light is easily leaked at the cross mark of the non-display area at the edge of the display panel. A mask having the same shape and dimension as those of a cross mark is adopted to form a light shielding layer, such that a shape of the opening of the light shielding layer corresponding to the cross mark is same as the shape of the cross mark. Since the cross mark is made of opaque metal materials, when the edge of the opening of the light shielding layer is coincident with the cross marks, the light leakage problem of the display panel can be effectively prevented, thereby improving the edge leakage or the reflective whitening of the front frameless display panel.

### DESCRIPTION OF DRAWINGS

In order to more clearly illustrate the technical solutions in the embodiments or the prior art, the drawings to be used in the descriptions of the embodiments or the prior art will be briefly described below. Obviously, the drawings in the following description are merely embodiments of the present disclosure. For those of ordinary skill in the art, other drawings may be obtained from the drawings without any creative work.

FIG. 1 is a partial schematic view of a display panel in the prior art.

FIG. 2 is a partial schematic view of a light shielding layer of an embodiment.

FIG. 3 is a schematic view of a display panel of an embodiment.

FIG. 4 is a side view of a display panel in an embodiment.

FIG. 5 is a schematic view of a display device of an embodiment.

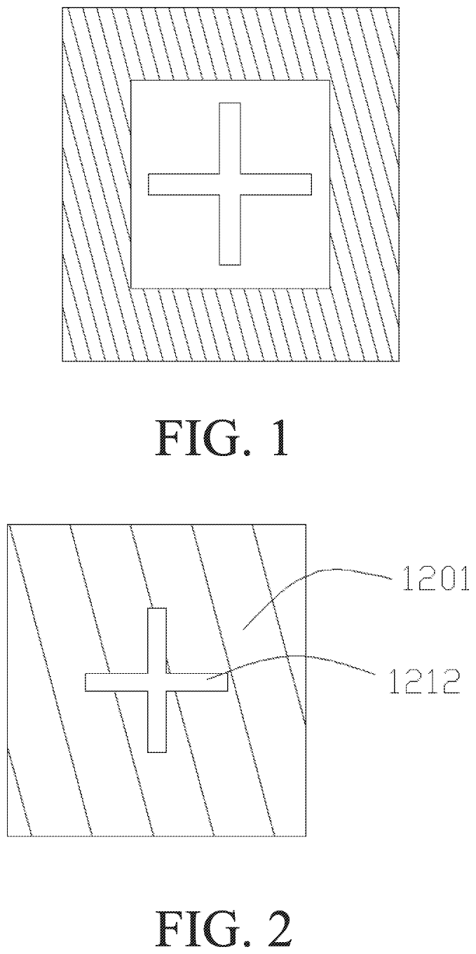

In the figures:

| | |
|---|---|
| 1 display device; | |
| 10 display panel; | 11 display area; |
| 12 non-display area; | 121 marked area; |
| 122 light shielding area; | 110 array substrate; |
| 120 color film substrate; | 1201 light shielding layer; |
| 1211 mark; | 1212 opening; |

### DETAILED DESCRIPTION OF EMBODIMENTS

Preferred embodiments of the present disclosure are described below with reference to the accompanying drawings, which demonstrate that the invention can be implemented. The embodiments of the present disclosure can fully introduce the invention to those skilled in the art, and make the technical content clearer and easier to understand. The present disclosure may be embodied in many alternative forms, and the scope of the present disclosure should not be construed as being limited to the embodiments mentioned herein.

In the drawings, structurally identical components are denoted by the same reference numerals, and structurally or functionally similar components are denoted by like reference numerals. Dimension and thickness of each component shown in the drawings are arbitrarily shown, and the present disclosure does not limit the dimension and the thickness of each component. In order to make the illustration clearer, some parts of the drawings appropriately exaggerate the thickness of the parts.

In addition, the following description of the various embodiments of the present disclosure refers to the drawings, to illustrate the preferred embodiment that the present disclosure can be implemented. Orientational relationships represented by directional terms mentioned in the present disclosure, such as “up”, “down”, “front”, “rear”, “left”, “right”, “inner”, “outer”, “lateral”, etc. are orientational relationships based on illustration of the drawings. So, the orientational relationships used are for a better and clearer describing and understanding of the present disclosure, rather than indicating or implying that the device or element is intended to have a particular orientation, or is constructed and operated in a particular orientation and therefore should not be interpreted as a limitation of the invention. In addition, terms such as “first” and “second” are used herein for purposes of description, and should not be interpreted as indication or implication of relative importance. When some of the components are described as being “on” another component, the components may be placed directly on the other component; there may also be an intermediate component that is placed in the middle, the components are placed on the intermediate component, and the intermediate component is placed on the other component.

When a component is described as “mounted to” or “connected to” another component, it can be understood as directly “mounted” or “connected”, or the component is indirectly “mounted to” or “connected to” the other component through an intermediate component.

### EMBODIMENT

In this embodiment, a display panel 10 of the present disclosure includes a display area 11 and a non-display area 12 surrounding the display area 11.

The display panel 10 is rectangular, and has four corners located in diagonal lines.

The display area 11 is a photic area, and is for displaying images of the display panel 10.

The non-display area 12 includes a marked area 121 and a light shielding area 122.

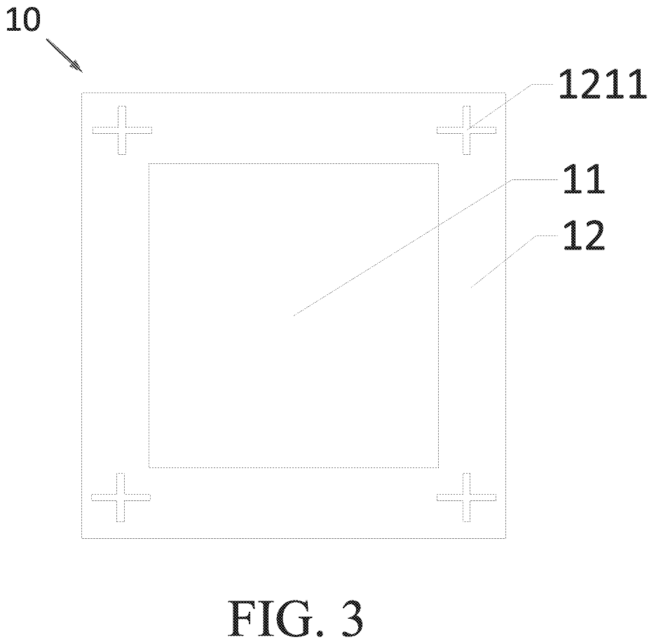

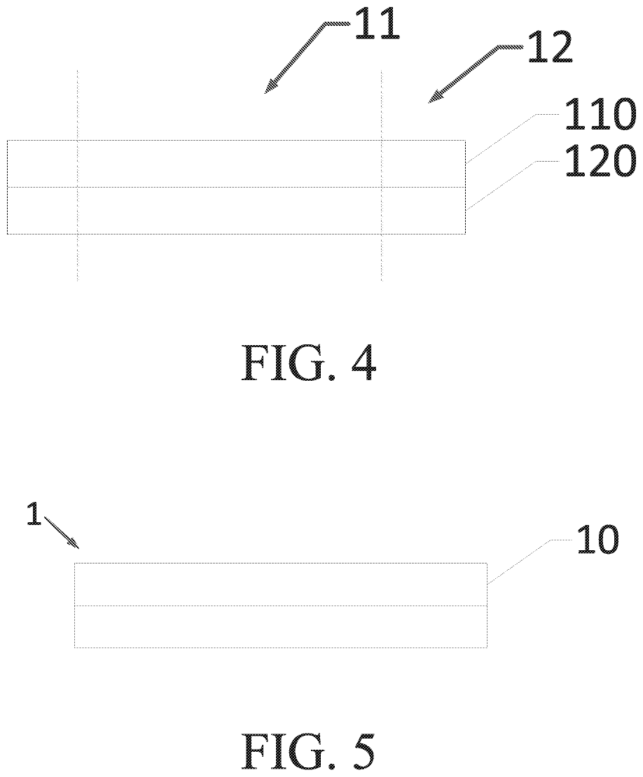

As shown in FIG. 3 and FIG. 4, the marked area 121 is arranged in the non-display area 12. In this embodiment, there are four marks 1211 in the marked area 121. A shape of the marks 1211 may be cross-shaped, square, L shaped, or circular. In this embodiment, the shape of the marks 1211 is a cross-shape. The marks 1211 include a lateral strip and a longitudinal strip, which are crossed to form the cross-shape. Both lengths of the lateral strip and the longitudinal strip are less than or equal to 0.3 mm.

The marks 1211 are respectively located in four corners of the display panel 10. The marks 1211 are configured to later recognize the display panel 10.

Specifically, the display panel 10 includes an array substrate 110 and a color film substrate 120 disposed opposite to the array substrate 110.

The marks 1211 are arranged on the array substrate 110, and the color film substrate 120 is provided with a light shielding layer 1201 thereon. The light shielding layer covers the non-display area of the color film substrate 120 to facilitate follow-up devices to recognize the marks 1211.

As shown in FIG. 2, the light shielding area 122 is provided with a light shielding layer 1201. The light shielding layer 1201 is laminated on the marked area 121 of the non-display area 12. Openings 12011 corresponding to the marks 1211 are defined in the light shielding layer 1201, so that the marks 1211 are not sheltered by the light shielding layer 1201.

Specifically, the light shielding layer 1201 is formed on the color film substrate 120 to shelter the non-display area of the color film substrate 120, thereby preventing light leakage of the non-display area, which may cause display abnormity of the display panel 10.

The marks 1211 are made of light-shielding opaque metal materials. Generally, in prior arts, square openings are correspondingly defined in the light shielding layer 1201 of the color film substrate 120 to expose the marks 1211 on the color film substrate 120, thereby facilitating devices to identify and orient the marks 1211.

However, to ensure the marks 1211 are completely exposed on the color film substrate 120, an area of the square openings is greater than that of the marks 1211, which may cause light leakage of the color film substrate 120, and thereby causing display abnormity of the display panel 10.

In this embodiment, the light shielding layer 1201 is made by a special mask, and holes are defined in the mask. Each hole has a same shape and dimension as that of the corresponding mark 1211, such that during forming the light shielding layer 1201, the openings 1212 defined in the light shielding layer 1201 have the same shape as the marks 1211. In order to prevent the color film substrate 120 from leaking light, the dimension of the opening 1212 is about 3 μm to 5 μm less than that of the marks 1211. Specifically, the opening 1212 also include a lateral groove and a longitudinal groove, which are crossed to form the cross-shape. A length of the lateral groove of the openings 1212 is about 3 μm to 5 μm less than that of the lateral strip of the marks 1211. Identically, a length of the longitudinal groove of the openings 1212 is about 3 μm to 5 μm less than that of the longitudinal strip of the marks 1211.

In order to completely expose the marks 1211 on the color film substrate 120, and to ensure that the marks 1211 can be identified and oriented, the dimension of the marks 1211 is 3 μm to 5 μm greater than that of marks commonly used in the prior art.

As shown in FIG. 5, in this embodiment, a display device 1 of the present disclosure includes the display panel 10. Main technical features of the display device 1 are all shown in the display panel 10, so remaining components of the display device 1 are not described in detail.

Finally, it should be stated that: the above embodiments are only used to illustrate the technical solutions of the present disclosure, and are not limited thereto. Although the present disclosure has been described in detail with reference to the foregoing embodiments, it will be understood by those of ordinary skill in the art that the technical solutions described in the foregoing embodiments may be modified or equivalently substituted for some or all of the technical features, and the modifications or substitutions do not depart from the scope of the technical solutions of the embodiments of the present disclosure.

What is claimed is:

1. A display panel, comprising:
a display area; and
a non-display area surrounding the display area;
wherein a marked area is arranged in the non-display area and comprises at least two marks; and
wherein a light shielding area is provided with a light shielding layer, the light shielding layer is laminated on the marked area of the non-display area, and openings corresponding to the at least two marks are defined in the light shielding layer.

2. The display panel as claimed in claim 1, further comprising:
an array substrate located in the non-display area, wherein the at least two marks are arranged on the array substrate; and
a color film substrate disposed opposite to the array substrate and located in the non-display area, wherein the light shielding layer is laminated on the color film substrate.

3. The display panel as claimed in claim 1, wherein dimensions and shapes of the openings are same as dimensions and shapes of the at least two marks.

4. The display panel as claimed in claim 1, wherein a projection on the marked area of the openings completely falls within an area of the at least two marks.

5. The display panel as claimed in claim 4, wherein dimensions of the opening are 3 μm to 5 μm less than dimensions of the at least two marks.

6. The display panel as claimed in claim 1, wherein the at least two marks are made of opaque metal materials.

7. The display panel as claimed in claim 1, wherein a maximum diameter of the at least two marks is less than 0.3 mm.

8. The display panel as claimed in claim 1, wherein the at least two marks are distributed around the array substrate.

9. The display panel as claimed in claim 1, wherein shapes of the at least two marks are at least one of a cross shape, a square shape, an L shape, or a circular shape.

10. A display device, wherein the display device comprises the display panel as claimed in claim 1.
